(19) United States
(12) Patent Application Publication
(10) Pub. No.: US 2006/0270104 A1
(43) Pub. Date: Nov. 30, 2006

(54) Method for attaching dice to a package and arrangement of dice in a package

(76) Inventors: Octavio Trovarelli, Dresden (DE); Sebastian Mueller, Chemnitz (DE)

Correspondence Address: SLATER & MATSIL LLP, 17950 PRESTON ROAD, SUITE 1000, DALLAS, TX, 75252, US

(21) Appl. No.: 11/121,167

(22) Filed: May 3, 2005

(51) Int. Cl. H01L 21/00

(52) U.S. Cl. 438/106

(57) ABSTRACT

The invention relates to a method and arrangement for assembling and packaging single and multiple semiconductor dice with an intermediate arranged interposer. The interposer is arranged onto the backside of a die within the wafer composite and thereby during the wafer level process. Preferably the interposer is printed by a stencil printing process.

### TECHNICAL FIELD

The invention relates to method and arrangement for assembling and packaging single and multiple semiconductor dice with an intermediate arranged interposer.

### BACKGROUND

For assembling a package of dice, at least one die is mounted on a package substrate by arranging an adhesive material intermediate the package and the die. Increasingly, a second die is positioned onto the top of the first die. In the same way, further dice can be mounted on the second die.

In a standard process, the bond pads on a die are connected to contact pads on the substrate by wires bonded on the bond pads and the contact pads. In contrast thereto flip-chip technology connects the bond pads with the contact pads by solder bumps conductive adhesive. Therefore, the die is turned around so that its active surface is opposite to the upper surface of the substrate. Furthermore, the bond pads are opposite to the contact pads respectively. Solder balls are arranged either on the contact pads of the substrate or on the bond pads of the die. By applying a solder reflow process the die is connected with the substrate.

For increasing the functionality of semiconductor devices a second die is attached on the upper surface of the first die. Also, the second die is connected with the substrate by wires bonded in the same manner. The bond pads are arranged on the active surface of a die. In this way a third die can be mounted on the second die and so on.

In the case the bottom die of two adjacent dice, i.e., the die with the closest distance to the substrate, are connected with wires and both dice have the same size, a space for the wires has to been excited by the usage of an interposer or a spacer between the two dice in order to protect the bond wires of the bottom die.

After attaching all dice and connecting with wires the package is enclosed with a mold compound. Thereby the mold compound also flows between the substrate and the die or between the dice if there is a space.

The interposer is normally made of a piece of silicon with adhesive on both sides for attaching at the surface of the bottom die on the backside of the upper die or a spacer is made of a polymer material.

Usually interposers or spacers are attached at die level of the process, i.e., during the stack assembly process. In U.S. Patent Application Publication No. 2004/0201088 A1, an attachment of spacers is disclosed wherein spacers made of polymer material are attached on the upper surface, which is also the active surface in the process die level after adhering the bottom chip onto the substrate. Arranging the interposers or the spacers in the die level reduces the productivity.

The productivity can be increased by arranging the interposers or spacers in the wafer level of the process.

A wafer has an active surface including a redistribution layer and a back surface. Furthermore, the wafer includes a plurality of unsingulated semiconductor dice.

Usually the wafer is provided with a dicing tape onto the back surface. Thereafter the wafer is diced from the active surface into singulated dice. Thereafter the whole composite of singulated dice is provided with a grinding tape on the active surface and removing the dicing tape and thereafter the composite of dice is grinded on the backside reducing the thickness of the dice.

In U.S. Patent Publication Application No. 2004/0197955 A1 an attachment of an interposer at the wafer level of the process is disclosed. Therein an interposer is attached to the wafer onto the active side before dicing. Thereafter the wafer together with the interposer is diced from the backside. In addition, this interposer is not suitable for attaching dice to a die package because it is configured as a package substrate interconnecting to the exterior of the package. The dicing of the wafer in the disclosed manner could cause damaging on the active surface.

### SUMMARY OF THE INVENTION

In one aspect, the invention increases the productivity of die packaging by attaching the interposer in the wafer level process without endangering any functionality of the dice.

Embodiments of the invention relate to methods and arrangements for assembling and packaging single and multiple semiconductor dice (or dies) with an intermediate arranged interposer. In one exemplary embodiment, the invention provides a method for attaching an interposer at dice in wafer level with the following steps:

providing a wafer having an active surface including a redistribution layer, having a back surface and including a plurality of unsingulated semiconductor dice;

providing the wafer with a dicing tape onto the back surface;

dicing the wafer from the active surface into singulated dice;

providing the composite of singulated dice with a grinding tape onto the active surface and removing the dicing tape;

grinding the composite of dice on the backside;

providing each die with an interposer on the grinded surface, the interposer having a mounting surface a distance from the grinded surface according to the high of the interposer;

picking a die from the composite of dice; and

adhering the die with the mounting surface of the interposer onto a surface of an underlying substrate.

With this method all dice are processed at the same time and under the same conditions. The dice are diced from the active side avoiding damaging the structure of the dice. Furthermore, no additional spacer-attach process at die level is necessary and the second die (daughter die or top die) can be attached immediately after the wire bonding process of the bottom die (mother die). Generally the die-attach process stability is improved.

A die with an interposer as mentioned above can be mounted as a daughter die on a mother die as well as such a die can be mounted also on a package substrate.

In a preferred embodiment the interposer is applied by a stencil printing process. Thereby a standard stencil printing process can be used.

Depending on the stencil design there is more effective area for adhesion between mold compound and dice in package.

Embodiments of the invention save silicon spacer and glue material. Furthermore, it is another advantage that a larger throughput due to a simplified die-attach process can be achieved.

In another embodiment, the invention provides an arrangement of dice in a package. The arrangement includes:

a packaging substrate having an upper side with first bonding pads on the upper side;

a first die with an active surface with second bonding pads on the active surface and a backside, the first die is mounted on the packaging substrate with its backside lying opposite to the upper surface wherein the first bonding pads are electrically connected to the bonding pads;

a second die with an active surface with third bonding pads on their active surface and a backside, the second die is mounted onto the active surface of the first die with the backside of the second die opposite to the active surface of the first die with an interposer intermediate arranged between the active surface of the first die and the backside of the second die printed on the backside and glued to the die active side of the first die.

With this arrangement, advantages mentioned above can be achieved.

### BRIEF DESCRIPTION OF THE DRAWINGS

The invention will be explained in more detail below using exemplary embodiments. In the associated drawings:

FIGS. 1a-1e (collectively FIG. 1) show steps in the dicing before grinding wafer level process common with the prior art;

FIGS. 2a-2f (collectively FIG. 2) show steps in a grinding before dicing wafer level process for preparing the inventive steps;

FIG. 3 shows the inventive stencil printing of interposers in the wafer level process;

FIG. 4 shows a stack of two dice with an intermediate arranged stencil printed interposer;

FIG. 5 shows the stack according to FIG. 4 with a mold compound encapsulation;

FIGS. 6a-6f (collectively FIG. 6) show several patterns for designing the interposers in top view;

FIG. 7 shows second embodiment of the invention by printing an adhesive material;

FIG. 8 shows a stack of two dice with an intermediate arranged printed adhesive material;

FIG. 9 shows the stack according to FIG. 8 with a mold compound encapsulation;

FIGS. 10a-10c (collectively FIG. 10) show a third embodiment of the invention by laminating with a tape and structuring by UV radiation;

FIG. 11 shows a stack of two dice with a taped adhesive material as interposer between the two dice and the bottom die and the substrate; and

FIG. 12 shows the stack according to FIG. 11 with a mold compound encapsulation.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

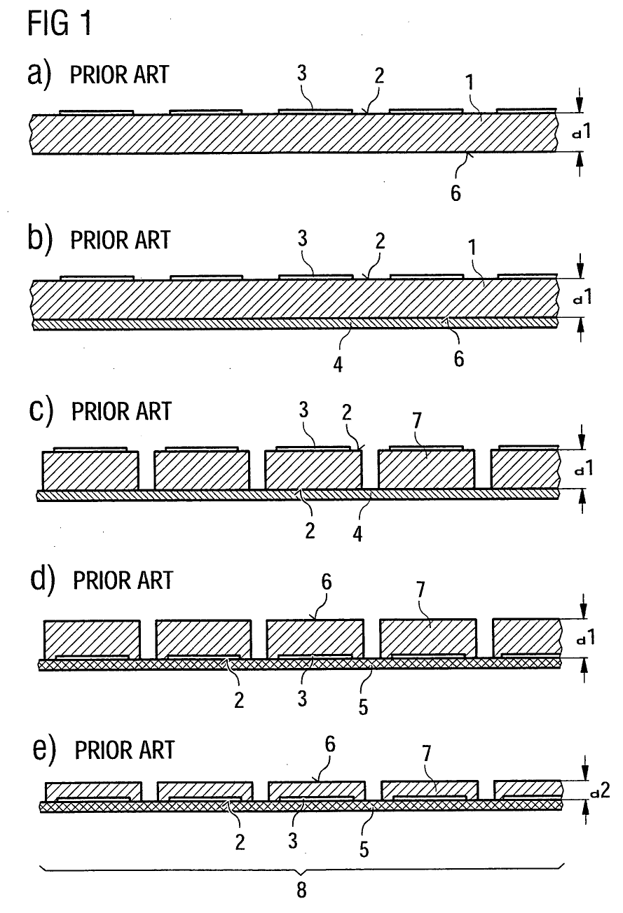

As illustrated in FIG. 1a, a wafer 1 is provided with an active surface 2 with a schematically shown redistribution layer 3. FIG. 1a illustrates the dicing before grinding process. In FIG. 1b the backside 6 is provided with a dicing tape 4. Thereafter, as shown in FIG. 1c, the wafer 1 is diced into multiple dice 7. After dicing, the dicing tape 4 is removed and a grinding tape 5 is added to the active surface 2 of the wafer 1, as shown in FIG. 1d. This grinding tape 5 protects the active surface 2 in the following grinding process. The backside 6 is grinded. Within the grinding process the thickness d1 of the wafer 1 as shown in FIGS. 1a to 1d to a thickness d2 as shown in FIG. 1e and the following figures.

These dice 7 are remaining in the wafer composite 8 because they are still held by the grinding tape 5.

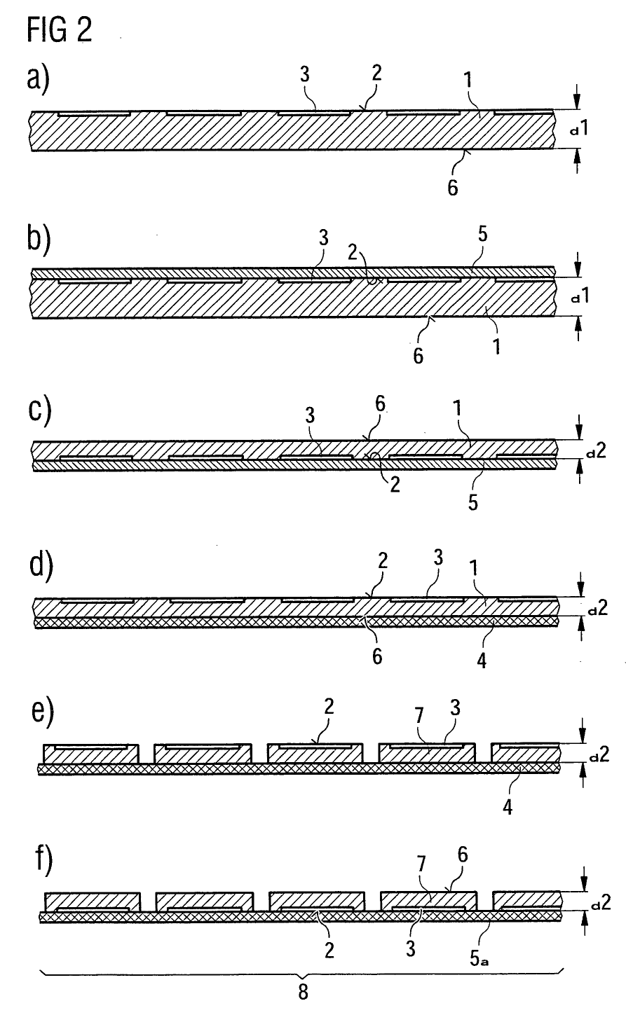

As illustrated in FIG. 2a, a wafer 1 is provided with an active surface 2 with a schematically shown redistribution layer 3. FIGS. 2a-2f illustrate the grinding before dicing process. As shown in FIG. 2b, the active surface is provided with a grinding tape 5. This grinding tape 5 protects the active surface 2 in the following grinding process. Within the grinding process the thickness d1 of the wafer as shown in FIGS. 2a and 2b to a thickness d2 as shown in FIG. 2c and the following figures.

After grinding the grinding tape 5 is removed and a dicing tape 4 is added to the backside 6 of the wafer 1. Thereafter the wafer 1 is diced into multiple dice 7. These steps are shown in FIGS. 2d and 2e.

To arrange the interposer 9 on the backside as described in the following, the grinding before dicing process is performed and then the wafer composite 8 is turned. Therefore a fixing tape 5a is used. The fixing tape is applied to the active surface of the dice 7 and the dicing tape 4 is removed as shown in FIG. 2f. Thereby the dice 7 remains in the wafer composite 8 because they are held by the fixing tape 5a.

When the interposer 9 as described below is arranged at the active surface 2, it is not necessary to use the fixing tape 5a because the active surface is uncovered in this state.

When the dice 7 are held either by grinding tape 5 by applying the dicing before grinding process or by the fixing tape 5a by applying the grinding before dicing process the following described steps can be applied for arranging interposers 9 on the backside 6.

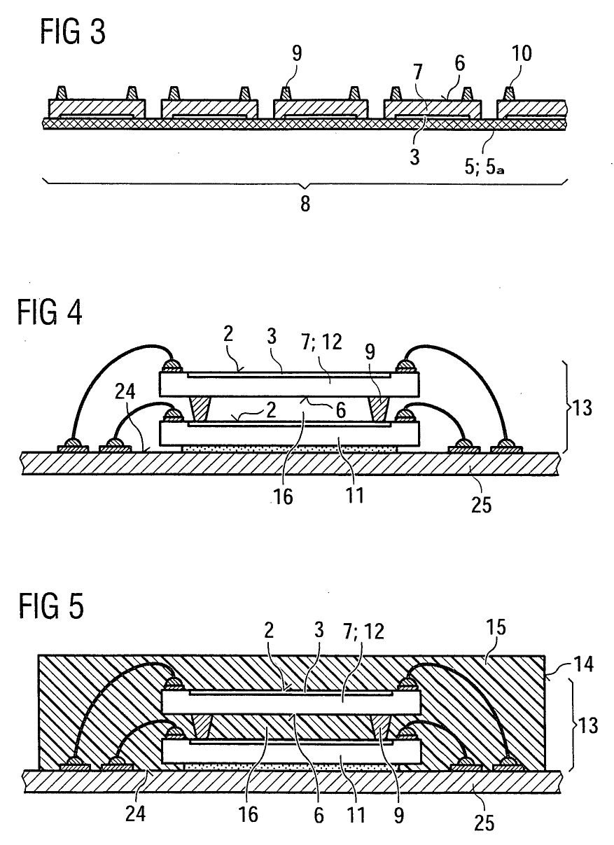

As shown in FIG. 3, interposers 9 are printed onto the active surface 2 of the dice 7. These interposers 9 can be made a non adhesive material. In this case the contact surface 10 of each interposer 9 can be provided with an adhesive (not shown), for instance with a further stencil printing process, possibly with the same stencil, or the surface of the substrate whereon the interposer 9 is applied is provided with an adhesive for fixing the die 7 on the substrate. Otherwise the stencil printed interposers 9 can be provided with adhesive properties themselves.

As shown in FIG. 4, a die 7 provided with interposers 9 is picked up from the wafer composite 8 and deposited on a bottom die 11 as the substrate. The not shown adhesive material between the contact surface 10 and the active surface 2 of the bottom die 11 or the adhesive property of the interposers 9 are fixing the top die 12 on the bottom die 11.

As shown in FIG. 5 thereafter the stack 13 is encapsulated with a mold compound encapsulation 14. The mold compound material 15 is a resin, which is liquid during the molding process. Thereby it flows also into the space 16 between the bottom die 11 and the top die 12. After curing the mold compound it fixes the both dice 11 and 12 irreversibly.

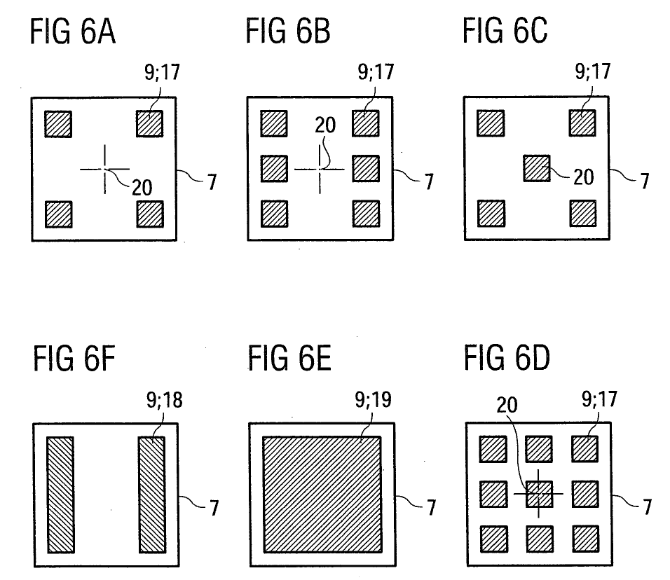

As shown in FIGS. 6a-6d the interposers 9 can be designed in several patterns. They can be designed as quadratic pads 17 as shown in FIGS. 6a to 6d. They can also be designed in rectangular stripe shaped form 18 as shown in FIG. 6f or as a closed area 19 as shown in FIG. 6e. All patterns are symmetrically arranged to the centre 20 of the die 7.

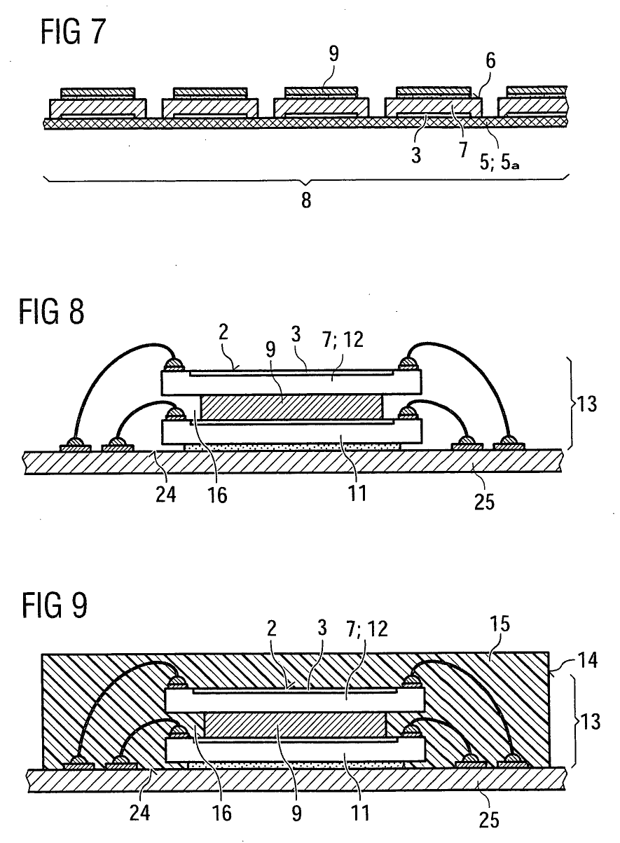

As shown in FIG. 7, the interposer 9 is made of an adhesive material, preferably a thermal active material. It can be printed or dispensed. After a drying process wherein the adhesive material becomes a tough property the dice 7 can be handled. As shown in FIG. 8, the die 7 can be picked up from the wafer composite 8 and applied to the bottom die 11 as top die 12 of the stack 13. The stack 13 is exposed a higher temperature and the adhesive material is cured.

As shown in FIG. 9 the stack 13 is also encapsulated by a mold compound material 15 making an encapsulation 14.

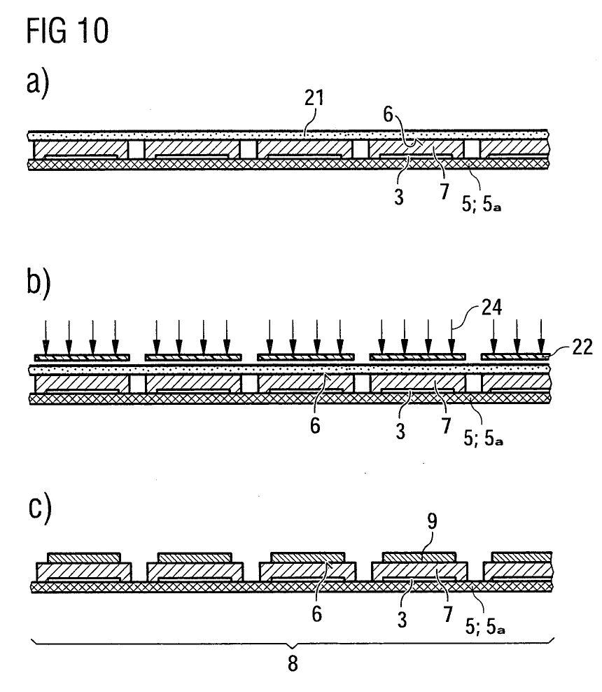

As shown in FIG. 10 alternatively the wafer composite 8 is provided with a die attach tape material 21 on the active surfaces 2 of the dice 7 depicted in FIG. 10a. By applying a mask 22, the tape material 21 is radiated with an UV light radiation 23 as shown in FIG. 10b. A tape release process follows as shown in FIG. 10c and the interposers 9 made of adhesive material are finished.

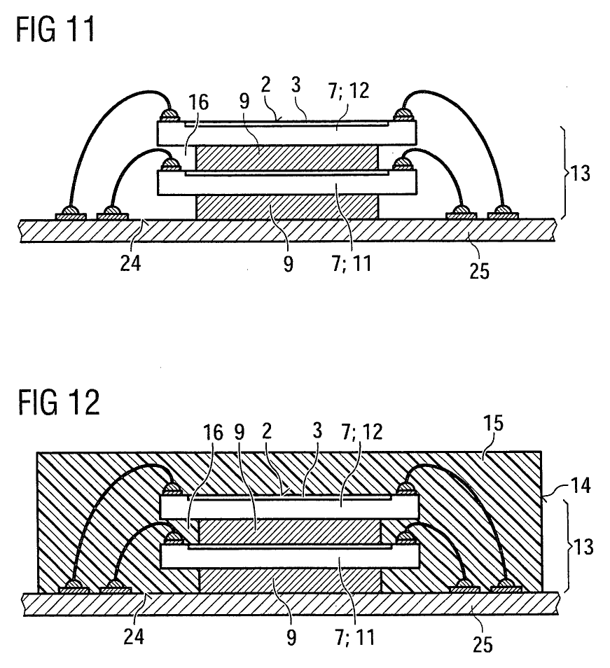

As shown in FIG. 11 the top die 12 as well as the bottom die 11 is provided with an interposer 9 manufactured in the inventive manner. At first the bottom die 11 is picked up from the same or another wafer composite and is adhered to the upper surface 24 of the substrate 25. After curing the adhesive material of the interposer 9 the top die 12 is mounted in the same manner. As shown in FIG. 12, the stack 13 is also encapsulated.

What is claimed is:

1. A method for attaching a die to a die package, the method comprising:
providing a wafer having an active surface that includes a redistribution layer, the wafer having a back surface, and the wafer including a plurality of unsingulated semiconductor dice;
providing the wafer with a dicing tape onto the back surface;
dicing the wafer into singulated dice;
providing the singulated dice with a grinding tape onto the active surface and removing the dicing tape;
grinding the singulated dice on the back surface;
providing each die with an interposer on the back surface, the interposer having a mounting surface;
picking a first die from the singulated dice; and
adhering the first die with the mounting surface of the interposer onto a surface of a substrate.

2. The method as claimed in claim 1, wherein the substrate comprises a package substrate.

3. The method as claimed in claim 1, wherein the substrate comprises a second die.

4. The method as claimed in claim 3, wherein the second die is provided with an interposer, the second die being manufactured in the same manner as the first die.

5. The method as claimed in claim 1, wherein the substrate comprises a package substrate, the method further comprising adhering a second die on the first die and encapsulating the first and second dice.

6. The method as claimed in claim 1, wherein providing each die with an interposer comprises applying the interposer by a stencil printing process.

7. The method as claimed in claim 6, wherein the interposer is made of an interposer material and wherein adhering the first die comprises adding an adhesive material between the mounting surface and the surface of the substrate.

8. The method as claimed in claim 6, wherein the interposer is structured in a pattern only partially covering the surface on the back surface of each die.

9. The method as claimed in claim 6, wherein the interposer is made of an adhesive material.

10. The method as claimed in claim 9, wherein the adhesive material comprises a thermal active material and wherein adhering the first die comprises placing the first die onto the substrate at a temperature where the adhesive material is not curing and increasing the temperature such that the adhesive material begins curing.

11. The method as claimed in claim 10, wherein substrate comprises a second die.

12. The method as claimed in claim 9, wherein providing each die with an interposer comprises:
laminating the singulated dice with a die attach tape material on the back surface of the dice;
structuring the die attach tape material by radiating ultraviolet light radiation through a mask with mask openings; and
releasing the die attach tape with radiated parts of the adhesive.

13. A method for attaching a die to a die package, the method comprising:
providing a wafer having an active surface that includes a redistribution layer, the wafer having a back surface, wherein the wafer includes a plurality of unsingulated semiconductor dice;
providing the wafer with a grinding tape onto the active surface;
grinding the back surface of the wafer;
providing the back surface of the wafer with a dicing tape and removing the grinding tape;
dicing the wafer from the active surface into singulated dice;
providing the singulated dice with a fixing tape on the active surface and removing the dicing tape;
providing each die with an interposer on the grinded back surface, the interposer having a mounting surface;
picking a first die from the singulated dice; and
adhering the mounting surface of the interposer of the first die with onto a surface of a substrate.

14. The method as claimed in claim 13, wherein the substrate comprises a package substrate.

15. The method as claimed in claim 13, wherein the substrate comprises a second die.

16. The method as claimed in claim 16, wherein the second die is provided with an interposer, the second die being manufactured in the same manner as the first die.

17. The method as claimed in claim 13, wherein the substrate comprises a package substrate, the method further comprising adhering a second die on the first die, the second die being provided with an interposer.

18. The method as claimed in claim 13, wherein providing each die with an interposer comprises applying the interposer by a stencil printing process.

19. The method as claimed in claim 18, wherein the interposer is made of an interposer material and wherein adhering the first die comprises adding an adhesive material between the mounting surface and the surface of the substrate.

20. The method as claimed in claim 18, wherein providing each die with an interposer comprises structuring the interposer in a pattern only partially covering the surface on the back surface of the die.

21. The method as claimed in claim 18, wherein the interposer comprises an adhesive material.

22. The method as claimed in claim 21, wherein the adhesive material comprises a thermal active material and wherein adhering the first die comprises placing the first die onto the substrate and heating the substrate to cure the thermal active adhesive.

23. The method as claimed in claim 22, wherein the substrate comprises a second die.

24. The method as claimed in claim 21, wherein providing each die with an interposer comprises:
laminating the singulated dice with a die attach tape material on the back surface of the dice;
structuring the die attach tape material by radiating ultraviolet light radiation through a mask with mask openings; and
releasing the die attach tape with radiated parts of the adhesive.

25. An arrangement of dice in a package, comprising
a package substrate having an upper side, first bonding pads disposed on the upper side of the package substrate;
a first die having an active surface and a backside, second bonding pads being disposed on the active surface of the first die, the backside of the first die being mounted on the upper side of the packaging substrate, wherein the first bonding pads are electrically coupled to the second bonding pads; and
a second die having an active surface and a backside, third bonding pads being disposed on the active surface of the second die, the backside of the second die being mounted onto the active surface of the first die; and
an interposer arranged between the active surface of the first die and the backside of the second die, the interposer being printed on the backside of the second die and adhered to the active side of the first die.

26. The arrangement as claimed in claim 25, wherein the interposer comprises a layer of adhesive material.

27. The arrangement as claimed in claim 25, wherein the interposer comprises multiple pads of adhesive material partially covering the backside of the second die.

28. The arrangement as claimed in claim 27, wherein the pads of adhesive material are arranged in a pattern shaped symmetrically to the central point of the die.

29. The arrangement as claimed in claim 28, wherein the pads comprise rectangular pads.

30. The arrangement as claimed in claim 29, wherein the pads comprise stripe-shaped pads.

31. The arrangement as claimed in claim 29, wherein the pads comprise quadratic pads.

32. The arrangement as claimed in claim 25, further comprising a second interposer between the backside of the first die and the upper surface of the package substrate, the second interposer being printed on the backside of the first die and adhered to the upper side of the package substrate.
